(19) United States
(12) Patent Application Publication
(10) Pub. No.: US 2004/0142098 A1
(43) Pub. Date: Jul. 22, 2004

(54) Using compacted organic materials in making white light emitting oleds

(75) Inventors: Syamal K. Ghosh, Rochester, NY (US); Tukaram K. Hatwar, Penfield, NY (US); Donn B. Carlton, Hamlin, NY (US)

Correspondence Address: Thomas H. Close, Patent Legal Staff, Eastman Kodak Company, 343 State Street, Rochester, NY, 14650-2201, US

(73) Assignee: Eastman Kodak Company

(21) Appl. No.: 10/348,118

(22) Filed: Jan. 21, 2003

(51) Int. Cl. C23C 16/00; B05D 5/06

(52) U.S. Cl. 427/68; 427/66; 427/255.6

(57) ABSTRACT

A method for depositing two or more emission layers in a white light emitting OLED device wherein each emission layer is formed by the steps including providing a solid compacted pellet of organic material including a mixture of at least one organic host and one organic dopant; placing such a solid compacted pellet of organic material inside a receptacle disposed in a physical vapor deposition chamber; positioning a substrate of a partially formed OLED device in the physical vapor deposition chamber in a spaced relationship with respect to the receptacle; evacuating the chamber to a reduced pressure; and applying heat to a surface of the solid compacted pellet of organic material disposed in the receptacle to cause at least a portion to sublime to provide a mixture of vapors of the organic materials including the host and the dopant to form an emission layer on the substrate.

### CROSS REFERENCE TO RELATED APPLICATIONS

Reference is made to commonly assigned U.S. patent application Ser. No. 09/898,369 filed Jul. 3, 2001 entitled “Method of Compacting Organic Material in Making An Organic Light-Emitting Device” by Van Slyke et al; U.S. patent application Ser. No. 10/073,690 filed Feb. 11, 2002, entitled “Using Organic Materials in Making An Organic Light-Emitting Device” by Ghosh et al, and U.S. patent application Ser. No. 10/195,947 filed Jul. 16, 2002, entitled “Compacting Moisture-Sensitive Organic Material in Making An Organic Light-Emitting Device” by Ghosh et al, the teachings of which are incorporated herein.

### FIELD OF THE INVENTION

The present invention relates to using a solid compacted pellet of organic materials including a host and dopants mixed therein to form emission layers for a white light emitting OLED display.

### BACKGROUND OF THE INVENTION

An organic light-emitting diode (OLED), also referred to as an organic electroluminescent device, can be constructed by sandwiching two or more organic layers between first and second electrodes. An OLED device includes a substrate, an anode, an organic hole-transporting layer, and an organic luminescent (emission) layer with suitable organic dopants, an organic electron-transporting layer, and a cathode. OLED devices are attractive because of their low driving voltage, high luminance, wide-angle viewing and capability for full-color flat emission displays. This multilayer OLED device is discussed in commonly-assigned U.S. Pat. Nos. 4,769,292 and 4,885,211.

Efficient white light producing OLED devices are considered as low cost alternative for several applications such as paper-thin light sources, backlights in LCD displays, automotive dome lights, and office lighting. White light producing OLED devices should be bright, efficient, and generally have Commission International d'Eclairage (CIE) chromaticity coordinates of about (0.33, 0.33). In any event, in accordance with this disclosure, white light is that light which is perceived by a user as having a white color.

The following patents and publications disclose the preparation of organic OLED devices capable of emitting white light, including an organic hole-transporting layer and an organic luminescent layer, and interposed between a pair of electrodes.

White light producing OLED devices have been reported before in commonly-assigned U.S. Pat. No. 5,683,823 wherein the luminescent layer includes red and blue light-emitting materials uniformly dispersed in a host emitting material. This device has good electroluminescent characteristics, but the concentration of the red and blue dopants are very small, such as 0.12% and 0.25% of the host material. These concentrations are difficult to control during large-scale manufacturing. Sato et al. in JP 07,142,169 discloses an OLED device, capable of emitting white light, made by sticking a blue light-emitting layer next to the hole-transporting layer and followed by a green light-emitting layer having a region containing a red fluorescent layer.

Kido et al., in Science, Vol. 267, p. 1332 (1995) and in APL Vol. 64, p. 815 (1994), report a white light producing OLED device. In this device three emitter layers with different carrier transport properties, each emitting blue, green or red light, are used to generate white light. Commonly-assigned U.S. Pat. No. 5,405,709 discloses another white emitting device, which is capable of emitting white light in response to hole-electron recombination, and comprises a fluorescent in a visible light range from bluish green to red. Recently, Deshpande et al., in Applied Physics Letters, Vol. 75, p. 888 (1999), published white OLED device using red, blue, and green luminescent layers separated by a hole blocking layer.

Organic materials, thickness of vapor-deposited organic layers, and layer configurations, useful in constructing an OLED device, are described, for example, in commonly-assigned U.S. Pat. Nos. 4,356,429; 4,539,507; 4,720,432; and 4,769,292, the disclosures of which are herein incorporated by reference.

Organic materials useful in making OLED devices, for example organic hole-transporting materials, organic light-emitting materials predoped with an organic dopant, and organic electron-transporting materials can have relatively complex molecular structures with relatively weak molecular bonding forces, so that care must be taken to avoid decomposition of the organic material(s) during physical vapor deposition.

The aforementioned organic materials are synthesized to a relatively high degree of purity, and are provided in the form of powders, flakes, or granules. Such powders, flakes or granules have been used heretofore for placement into a physical vapor deposition source wherein heat is applied for forming a vapor by sublimation or vaporization of the organic material, the vapor condensing on a substrate spaced apart from the deposition source to provide an organic layer thereon.

Several problems have been observed in using organic powders, flakes, or granules in physical vapor deposition:

(i) powders, flakes, or granules are difficult to handle because they can acquire electrostatic charges via a process referred to as triboelectric charging;

(ii) powders, flakes, or granules of organic materials generally have a relatively low physical density (expressed in terms of weight per unit volume) in a range from about 0.05 to about 0.2 g/cm³, compared to a physical density of an idealized solid organic material of about 1 g/cm³;

(iii) powders, flakes, or granules of organic materials have an undesirably low thermal conductivity, particularly when placed in a physical vapor deposition source which is disposed in a chamber evacuated to a reduced pressure as low as 10⁻⁶ Torr. Consequently, powder particles, flakes, or granules are heated only by radiative heating from a heated source, and by conductive heating of particles or flakes directly in contact with heated surfaces of the source. Powder particles, flakes, or granules which are not in contact with heated surfaces of the source are not effectively heated by conductive heating due to a relatively low particle-to-particle contact area; and

(iv) powders, flakes, or granules can have a relatively high ratio of surface area/volume of such particles and a correspondingly high propensity to entrap air and/or moisture between particles under ambient conditions. Consequently, a charge of organic powders, flakes, or granules loaded into a physical vapor deposition source which is disposed in a chamber must be thoroughly outgased by preheating the source once the chamber has been evacuated to a reduced pressure. If outgasing is omitted or is incomplete, particles can be ejected from the source together with a vapor stream during physical vapor-depositing an organic layer on a structure. A white OLED, having multiple emission layers, can be or can become functionally inoperative if such layers include particles or particulates.

Each one, or a combination, of the aforementioned aspects of organic powders, flakes, or granules can lead to nonuniform heating of such organic materials in physical vapor deposition sources with attendant spatially nonuniform sublimation or vaporization of organic material and can, therefore, result in potentially nonuniform vapor-deposited organic layers formed on a structure. Therefore, white OLED devices fabricated using organic powders, flakes or granules may not have high luminance efficiency.

### SUMMARY OF THE INVENTION

It is an object of the present invention to fabricate an efficient white OLED light emitting device.

The object of this invention is to provide a more simplified way to form emission layers in a white light emitting OLED device.

It is another object of the invention to provide an improved way of depositing emission layers by using a combination of dopant and host for each emission layer.

These objects are achieved in a method for depositing two or more emission layers in a white light emitting OLED device wherein each emission layer is formed by the steps comprising:

(a) providing a solid compacted pellet of organic material including a mixture of at least one organic host and one organic dopant;

(b) placing such a solid compacted pellet of organic material inside a receptacle disposed in a physical vapor deposition chamber;

(c) positioning a substrate of a partially formed OLED device in the physical vapor deposition chamber in a spaced relationship with respect to the receptacle;

(d) evacuating the chamber to a reduced pressure; and

(e) applying heat to a surface of the solid compacted pellet of organic material disposed in the receptacle to cause at least a portion to sublime to provide a mixture of vapors of the organic materials including the host and the dopant to form an emission layer on the substrate.

A feature of the present invention is that a solid compacted pellet of organic material including a host and at least one dopant mixed prior to the compaction process can be used in the vapor deposition of emission layers in a white light emitting OLED.

Another feature of the present invention is that fewer deposition sources are required as contrasted to co-evaporation to deposit a multiple emission layers for a white light emitting OLED.

### BRIEF DESCRIPTION OF THE DRAWINGS

FIG. 1 depicts a prior art OLED;

FIG. 2 depicts the schematic representation of a vacuum deposition chamber for OLED displays using the solid compacted pellet of organic material according to the present invention;

FIG. 3 shows an enlarged partial view of the evaporation source which is a part of the vacuum deposition chamber as shown in FIG. 2;

FIG. 4 is a schematic sectional view of a white light emitting OLED wherein yellow, blue and green emission layers were formed using compacted pellets; and

FIG. 5 is another schematic sectional view of a white light emitting OLED including yellow and blue emission layers.

The term “powder” is used herein to denote a quantity of individual particles, which can be flakes, granules, or mixtures of varied particles and shapes including single or plurality of molecular species.

### DETAILED DESCRIPTION OF THE INVENTION

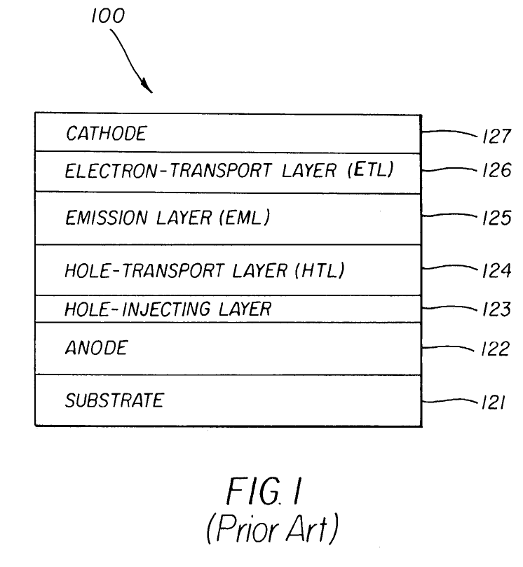

The organic layers of an OLED include an organic or organo-metallic material that produces light, known as electroluminescence (EL), as a result of electron-hole recombination in the layer. Hereinafter, the term “organic” will be taken to include both purely organic as well as organo-metallic materials. Turning to FIG. 1, a detailed structure of an OLED 100 of the prior art is shown, wherein an emission layer (EML) 125 is situated between a hole-transport layer (HTL) 124 and an electron-transport layer (ETL) 126. Each of these layers is composed predominantly of organic materials. The two transport layers 124 and 126 deliver holes from an anode 122 and electrons from a cathode 127, respectively, to the emission layer 125. An optional hole-injecting layer123 facilitates the injection of holes from the anode 122 to the HTL 124. The emission layer 125 functions as the primary site for electron-hole recombination and emission of the resulting electroluminescent (EL) light. In this respect, the functions of the individual organic layers are distinct and therefore can be optimized independently. Thus, the emission layer 125 can be optimized for a desirable EL color and high luminance efficiency. A substrate 121 provides mechanical support for the OLED 100 and for electrical leads connecting the OLED 100 to a source of electric current. Layers 122 through 127 together along with the substrate 121 comprise the OLED 100. Either the cathode 127 or both the anode 122 and the substrate 121, are transparent to the EL light.

When an electrical potential difference (not shown) is applied between the anode 122 and the cathode 127, the cathode 127 injects electron into the HTL 124, and they migrate across that layer to the emission layer 125. At the same time, holes are injected from the anode 122 into the HTL 124, and they migrate across that layer to the emission layer 125. The holes and electrons recombine in the emission layer 125, frequently near the junction between the HTL 124 and the emission layer 125. Part of the energy released by the recombination process is emitted as electroluminescnce which escapes through the transparent anode or cathode and/or the substrate.

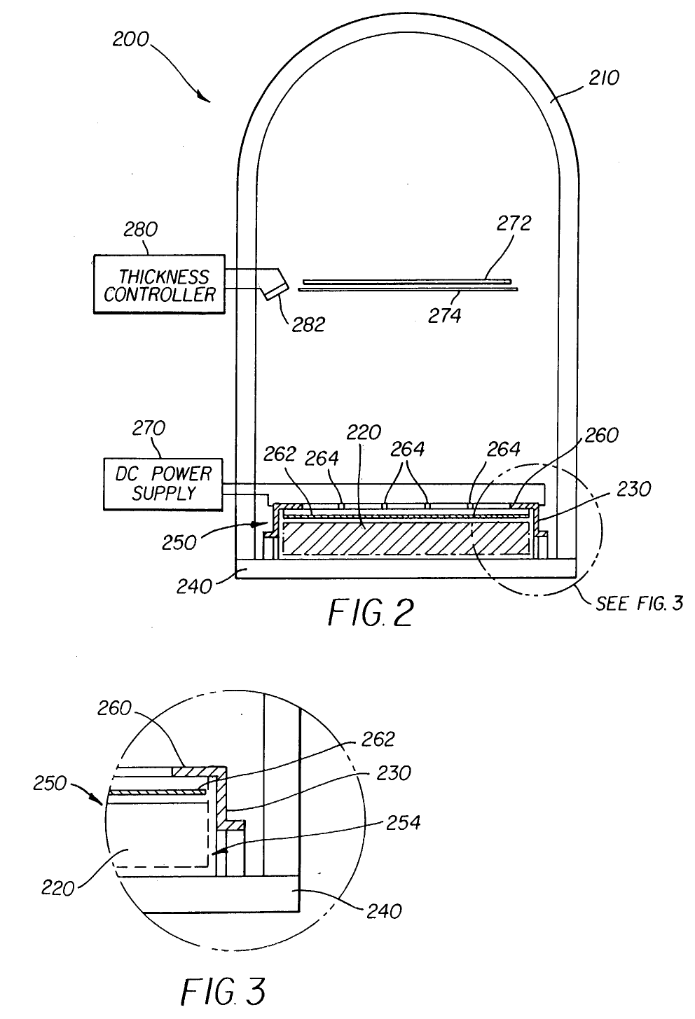

Referring to FIG. 2, there is shown a schematic of the physical vapor deposition chamber 200 for OLED displays including a bell jar 210 which is kept under ultra high vacuum, wherein a solid compacted pellet of organic material 220 is placed inside a receptacle or crucible 230 located on the base plate 240 of the vapor deposition chamber 200. An evaporation source 250 including the solid compacted pellet of organic material 220, the receptacle 230, a heater 260 and a baffle 262, is connected to a DC power supply 270 for providing electrical energy in order to evaporate or sublime the solid compacted pellet of organic material 220. The heater 260 and the baffle 262 are constructed using refractory and electrically conductive metals like Ta, Mo or W. The heater 260 is provided with a series of openings 264 in the form of a hole or a slit to permit organic vapor to escape from the evaporation source 250 for deposition on a suitable receiving substrate 272 which is anchored to a fixture spaced apart from the evaporation source 250. The substrate 272 is equipped with a rotatable shutter 274 to protect it from deposition of any unwanted vapor on to the substrate 270. A thickness controller 280 located outside the bell jar 210 controls the rate of vapor deposition on the substrate 272. The crystal 282 is placed in close proximity to the substrate 272 to measure accurately the rate of vapor deposition on to the substrate 272 wherein the crystal 282 is electrically connected to the thickness controller 280 which monitors the rate of vapor deposition from the solid compacted pellet of organic material 220.

In accordance with the present invention, two or more emission layers in a white light emitting OLED display were deposited using a solid compacted pellet of organic material, wherein each emission layer is formed by the steps comprising:

(a) providing a solid compacted pellet of organic material including a mixture of at least one organic host and one organic dopant;

(b) placing such a solid compacted pellet of organic material inside a crucible or receptacle disposed in a physical vapor deposition chamber;

(c) positioning a substrate of a partially formed OLED device in the physical vapor deposition chamber in a spaced relationship with respect to the receptacle;

(d) evacuating the chamber to a reduced pressure; and

(e) applying heat to a surface of the solid compacted pellet of organic material by electrically energizing the heater disposed in the evaporation source to cause at least a portion to sublime to provide a mixture of vapors of the organic materials including the host and the dopant(s) to form an emission layer on the substrate. The details of the construction of white light emitting displays are described hereinafter.

FIG. 3 is a partial enlarged view of the evaporation source 250 which is a part of the vapor deposition chamber 200 as shown in FIG. 2. The evaporation source 250 includes the solid compacted pellet of organic material 220, the heater 260, the baffle 262, and the receptacle 230. The receptacle 230 is made from electrically insulating and high temperature resistant materials like quartz or ceramic materials like alumina, zirconia, mullite or boron nitride. The heater 260 is anchored to an electrically insulating standoff 254.

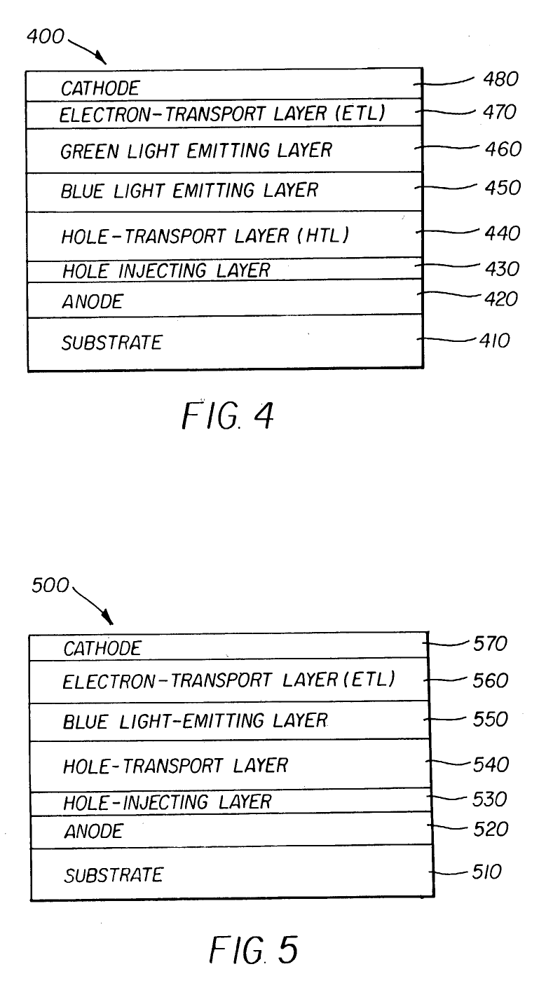

FIGS. 4-5 show cross-sectional schematics of the white light emitting OLED displays constructed in accordance with the present invention, wherein each emission layer such as yellow, blue and green was deposited from a single evaporation source using a compacted pellet comprising at least one organic host and one organic donor materials. The organic host and a known amount of organic donor are mixed homogeneously and placed inside a die cavity wherein pressure in the range of 2,000 to 5,000 psi is applied through two opposing punches to consolidate the mixture of organic powders to a compacted solid pellet. The die is generally heated to a set temperature not exceeding the glass-transition temperature of the organic materials prior to and during the compaction process.

Turning to FIG.4, a white light-emitting OLED device 400 has a light-transmissive substrate 410 on which is disposed a light-transmissive anode 420. The organic white light-emitting structure is formed between the anode 420 and a cathode 480. The organic white light-emitting structure includes three emission layers, in sequence, including: (1) an organic hole-transporting layer 440 which is formed by doping host NPB, namely 4.4′-Bis[N-phenylamino] biphenyl as described in commonly assigned U.S. Pat. No. 4,539,507 with Rubrene to emit yellow light, wherein the dopant concentration of Rubrene ranges from 2 to 5% by weight; (2) .an organic blue light-emitting layer 450, wherein a host 9,10-bis[N-(1-phenylamino)biphenyl (TBADN) is doped with TBP ranging in dopant concentration from 1 to 3%; and (3) an organic green light-emitting layer 460, wherein a host tris(8-quinolinolato-N1,08)aluminum (Alq) is doped with green emitting coumarin C545T described in commonly assigned U.S. Pat. No. 6,020,078, ranging in dopant concentration from 0.5 to 1.0% by weight. An organic electron-transporting layer 470.including Alq is deposited over the green emission layer 460. A hole-injecting layer.430 is deposited between the anode 420 and the hole-transporting layer 440. When an electrical potential difference (not shown) is applied between the anode 420 and the cathode 480, the cathode 480 will inject electrons into the electron-transporting layer 470, and the electrons will migrate across elecron-transporting layer 470 to the green light-emitting layer 460. At the same time, holes will be injected from the anode 420 into the hole-transport layer 440, which is doped with Rubrene to emit yellow light. The holes will migrate across the hole-transporting layer 440 and recombine with electrons at or near a junction formed between the hole-transport layer 440 and the blue light-emitting layer 450. When a migrating electron drops from its conduction band to a valance band in filling a hole, energy is released as light, and which is emitted through the light-transmissive anode 420 and substrate 410.

The organic OLED devices can be viewed as a diode, which is forward biased when the anode 420 is at a higher potential than the cathode 480. The anode 420 and cathode 480 of the organic OLED device can each take any convenient conventional form, such as any of the various forms disclosed in commonly-assigned U.S. Pat. No. 4,885,211. Operating voltage can be substantially reduced when using a low-work function cathode and a high-work function anode. The preferred cathodes are those constructed of a combination of a metal having a work function less than 4.0 eV and one other metal, preferably a metal having a work function greater than 4.0 eV. The Mg:Ag in commonly-assigned U.S. Pat. No. 4,885,211 constitutes one preferred cathode construction. The Al:Mg cathode in commonly-assigned U.S. Pat. No. 5,059,062 is another preferred cathode construction. Commonly-assigned U.S. Pat. No. 5,776,622 discloses the use of a LiF/Al bilayer to enhanced electron injection in organic OLED devices. Cathodes made of either Mg:Ag, Al:Mg or LiF/Al are opaque and displays cannot be viewed through the cathode. Recently, series of publications Gu et al. in APL 68, 2606 (1996); Burrows et al., J. Appl. Phys. 87, 3080 (2000); Parthasarathy et al. APL 72, 2138 9198); Parthasarathy et al. APL 76, 2128 (2000), and Hung et al. APL, 3209 (1999) have disclosed transparent cathode based on the combination of thin semitransparent metal (˜100 A) and indium-tin-oxide (ITO) on top of the metal. An organic layer of copper phthalocyanine (CuPc) also replaced thin metal.

Conventionally, anodes are formed of a conductive and transparent oxide. Indium tin oxide has been widely used as the anode contact because of its transparency, good conductivity, and high-work function.

In a preferred embodiment, an anode 420 can be modified with a hole-injecting layer 430. The hole-injecting material can serve to improve the film formation property of subsequent organic layers and to facilitate injection of holes into the hole-transporting layer 440. Suitable materials for use in the hole-injecting layer 430 include, but are not limited to, porphyrinic compounds such as CuPC as described in commonly-assigned U.S. Pat. No. 4,720,432, and plasma-deposited fluorocarbon polymers (CFx) as described in commonly-assigned U.S. Pat. No. 6,208,075 and some aromatic amines, for example, m-MTDATA (4,4′,4″-tris[(3-methylphenyl)phenylamino]triphenylamine). Alternative hole-injecting materials reportedly useful in organic EL devices are described in EP 0 891 121 A1 and EP 1 029 909 A1. An example of material in such a hole-injecting layer are the fluorocarbon polymers, CFx, disclosed in commonly-assigned U.S. Pat. No. 6,208,075, the disclosure of which is incorporated herein by reference.

The OLED device of this invention is typically provided over a supporting substrate 410 where either the cathode or anode can be in contact with the substrate. The electrode in contact with the substrate is conveniently referred to as the bottom electrode. Conventionally, the bottom electrode is the anode, but this invention is not limited to that configuration. The substrate can either be light-transmissive or opaque, depending on the intended direction of light emission. The light-transmissive property is desirable for viewing the EL emission through the substrate. Transparent glass or plastic is commonly employed in such cases. For applications where the EL emission is viewed through the top electrode, the transmissive characteristic of the bottom support is immaterial, and therefore can be light-transmissive, light absorbing or light reflective. Substrates for use in this case include, but are not limited to, glass, plastic, semiconductor materials, silicon, ceramics, circuit board materials, and polished metal surface. Of course, it is necessary to provide in these device configurations a light-transparent top electrode.

Referring to FIG. 5, another white light-emitting OLED device 500 has a light-transmissive substrate 510 on which is disposed a light-transmissive anode 520. The organic white light-emitting structure is formed between the anode 520 and a cathode 570. The organic white light-emitting structure is comprised primarily of two emission layers, in sequence, including: (1) an organic hole-transporting layer 540 which is formed by doping NPB host with Rubrene to emit yellow light, wherein the dopant concentration of Rubrene ranges from 2 to 5% by weight; and (2) .an organic blue light-emitting layer 550, wherein a host TBADN is doped with TBP or OP 31 ranging in dopant concentration from 1 to 5% by weight. An organic electron-transporting layer 560 including Alq is deposited over the blue light emitting layer 550. A hole-injecting layer.530 is deposited between the anode 520 and the hole-transport layer 540. When an electrical potential difference (not shown) is applied between the anode 520 and the cathode 570, the cathode 570 will inject electrons into the electron-transporting layer 560, and the electrons will migrate across electron-transport layer 560 to the blue light-emitting layer 550. At the same time, holes will be injected from the anode 520 into the hole-transporting layer 540 which is doped with Rubrene to emit yellow light. The holes will migrate across the hole-transport layer 540 and recombine with electrons at or near a junction formed between the hole-transport layer 540 and the blue light-emitting layer 550. When a migrating electron drops from its conduction band to a valance band in filling a hole, energy is released as light, and which is emitted through the light-transmissive anode 520 and substrate 510. In a preferred embodiment, the anode 220 can be modified with a hole-injecting layer 530. The function and composition of the hole-injecting layer 530 has been described in details hereinbefore.

FIGS. 4-5 are specific examples of the white light-emitting OLED displays constructed by depositing each emission layer from a single compacted pellet of organic materials including at least one organic host and one organic dopant. Various organic dopants can be mixed with at least one organic host to deposit an emission layer which will emit either yellow, or blue or green light. Details of various combinations of hosts and dopants are described in commonly-assigned U.S. patent application Ser. No. 10/244,314 filed Sep. 16, 2002 entitled “White₁₃organic light-emitting devices with improved performance” by T. K. Hatwar, teachings of which is incorporated herein by reference.

The white OLED emission can be used to prepare a full-color device using red, green, and blue (RGB) color filters. The RGB filters may be deposited on the substrate (when light transmission is through the substrate), incorporated into the substrate, or deposited over the top electrode (when light transmission is through the top electrode). When depositing a RGB filter array over the top electrode, a buffer layer may be used to protect the top electrode. The buffer layer may comprise inorganic materials, for example, silicon oxides and nitrides, or organic materials, for example, polymers, or multiple layers of inorganic and organic materials. Methods for providing RGB filter arrays are well known in the art. Lithographic means, inkjet printing, and laser thermal transfer are just a few of the methods RGB filters may be provided.

This technique of producing a full-color display using white light plus RGB filters has several advantages over the precision shadow masking technology used for producing the full-color OLED displays. This technique does not require precision alignment, is low cost and easy to manufacture. The substrate itself contains thin film transistors to address the individual pixels. U.S. Pat. Nos. 5,550,066 and 5,684,365 to Ching and Hseih describe the addressing methods of the TFT substrates.

The invention has been described in detail with particular reference to certain preferred embodiments thereof, but it will be understood that variations and modifications can be effected within the spirit and scope of the invention.

### PARTS LIST

100 OLED

121 substrate

122 anode

123 hole-injecting layer

124 hole-transport layer (HTL)

125 emission layer (EML)

126 electron-transport layer (ETL)

127 cathode

200 vapor deposition chamber

210 bell jar

220 solid compacted pellet of organic material

230 receptacle

240 base plate

250 evaporation source

254 standoff

260 heater

262 baffle

264 opening

270 DC power supply

272 substrate

274 rotatable shutter

280 thickness controller

282 crystal

400 white light-transmitting OLED

410 substrate

420 anode

430 hole injecting layer

440 hole-transport layer (HTL)

450 blue light emitting layer

Parts List cont'd.

460 green light emitting layer

470 electron-transport layer (ETL)

480 cathode

500 white light-emitting OLED

510 substrate

520 anode

530 hole-injecting layer

540 hole-transport layer

550 blue light-emitting layer

560 electron-transport layer (ETL)

570 cathode

What is claimed is:

1. A method for depositing two or more emission layers in a white light emitting OLED device wherein each emission layer is formed by the steps comprising:
(a) providing a solid compacted pellet of organic material including a mixture of at least one organic host and one organic dopant;
(b) placing such a solid compacted pellet of organic material inside a receptacle disposed in a physical vapor deposition chamber;
(c) positioning a substrate of a partially formed OLED device in the physical vapor deposition chamber in a spaced relationship with respect to the receptacle;
(d) evacuating the chamber to a reduced pressure; and
(e) applying heat to a surface of the solid compacted pellet of organic material disposed in the receptacle to cause at least a portion to sublime to provide a mixture of vapors of the organic materials including the host and the dopant to form an emission layer on the substrate.

2. The method of claim 1 wherein there are two emission layers which emit yellow and blue light.

3. The method of claim 1 wherein there are three emission layers which emit yellow, blue and green light.

4. The method of claim 1 wherein the compacted pellets of organic material are formed, comprising the steps of:
(a) providing a sublimable organic material in a powder form;
(b) forming a mixture of the sublimable organic material comprising at least one organic host and one organic donor material;
(c) placing such mixture in a die and using two opposing punches to supply sufficient pressure to the mixture;
(d) applying heat to the die during or prior to applying pressure by the opposing punches to aid in the mixture of organic powders to consolidate into a solid pellet; and
(e) removing the pellet from the die.
